(19) United States
(12) Patent Application Publication
(10) Pub. No.: US 2026/0269178 A1
(43) Pub. Date: Sep. 10, 2026

(54) ADAPTIVE ILLUMINATION FOR A DUAL BEAM SYSTEM

(71) Applicant: FEI Company, Hillsboro, OR (US)

(72) Inventors: Tilman FRANKE, Munchen (DE); Thierry BOTTARO, Munchen (DE)

(21) Appl. No.: 19/072,519

(22) Filed: Mar. 6, 2025

(51) Int. Cl. H01J 37/22; G02B 21/16; H01J 37/06; H01J 37/08; H01J 37/26; H01J 37/305

(52) U.S. Cl. CPC H01J 37/226; G02B 21/16; H01J 37/06; H01J 37/08; H01J 37/222; H01J 37/3053; H01J 37/26; H01J 2237/31745; H01J 2237/31749

(57) ABSTRACT

Systems and methods are disclosed here for a charged particle dual beam (CPDB) system. In one example, the CPDB system includes an ion beam column coupled to a chamber surrounding a sample, and an electron beam column coupled to the vacuum chamber and having a focal point aligned with the sample at a eucentric point of the electron beam column and the ion beam column. The CPDB system further includes an optical light microscope, also coupled to the chamber, having a first field of view (FOV) that is to be superimposed with data collected using one or more of the ion beam column or the electron beam column. The optical light microscope includes an adaptive illumination device to adjust an area of illumination in the sample.

### FIELD OF THE INVENTION

The present disclosure relates to the field of charged particle microscopy. More specifically, the method and systems described herein pertain to modification of sample illumination during acquisition of images using charged particle microscopy.

### BACKGROUND

A charged particle dual beam (CPDB) system may be used to obtain thin sub-samples (e.g. lamellae) of a sample to be analyzed via a transmission electron microscope (TEM). For example, the CPDB system may facilitate milling of a sample, where the milling may be performed according to electron microscope images of the sample. In some examples, the CPDB system may further include an optical light microscope to illuminate the sample to assist in identifying regions of interest therein.

For example, the optical light microscope may irradiate an area of the sample that is within an initial field of view (FOV) of the optical light microscope. Interaction of the irradiated light with the sample may allow a structure in the sample to be identifiable within the FOV. A view of the sample may be magnified in order to observe the structure in greater detail, causing the FOV to be reduced relative to a previously viewed area of the sample. However, a region of the sample that is irradiated may remain unchanged despite a change in the FOV area. For example, a portion of the sample outside of a magnified FOV of the optical light microscope may remain illuminated although the portion is not observed within the magnified FOV. In some instances, prolonged exposure of the sample to illumination may have adverse effects on the sample, such as bleaching, devitrification, and generation of radicals, among others. As such, mitigation of superfluous illumination of a sample during analysis using a CPDB system is desirable.

### SUMMARY

As described herein, illumination of a sample for a CPDB system may be dynamically adjusted to reduce loss of sample integrity resulting from exposure to light. In at least one embodiment, a dual beam system includes an ion beam column coupled to a chamber surrounding a sample and an electron beam column coupled to the chamber and having a focal point aligned with the sample at a eucentric point of the electron beam column and the ion beam column. The dual beam system further includes an optical light microscope coupled to the chamber, the optical light microscope having a first field of view (FOV), the first FOV corresponding to an area of the sample that is illuminated by the optical light microscope, that is to be superimposed with data collected using one or more of the ion beam column or the electron beam column. The optical light microscope includes an adaptive illumination device to adjust illumination of the area of the sample.

In another embodiment, a method for a dual beam system includes identifying a region of interest (ROI) of a sample using an optical light microscope coupled to a chamber surrounding the sample, the chamber also coupled to an electron beam column and an ion beam column. The method also includes receiving a request for virtual magnification of a first FOV of the optical light microscope to a second FOV. In response to the received request, using an adaptive illumination device of the optical light microscope, illumination of the sample is adjusted in a region outside of the second FOV. The method further includes using the second FOV to apply to the sample one or more of an electron beam generated by the electron beam column or an ion beam generated by the ion beam column.

In yet another embodiment, a charged particle dual beam apparatus includes an electron beam column configured to scan a sample within a vacuum chamber using an electron beam, an ion beam column configured to apply an ion beam to the sample, and an optical light microscope having a FOV aligned with the sample and comprising an adaptive illumination device. The apparatus further includes a controller having executable instructions thereon that, when executed, cause the controller to identify one or more regions of interest (ROIs) in the sample using the optical light microscope and operate the adaptive illumination device to adjust illumination of the sample outside of a field of view (FOV) of the optical light microscope. The executable instructions further cause the controller to use one or more images obtained by the optical light microscope to apply, to the sample, one or more of the electron beam or the ion beam.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 illustrates a charged particle dual beam (CPDB) system with an integrative optical light microscope (iOLM) having an adaptive illumination device, in accordance with one embodiment.

FIG. 2 illustrates components of an optical light microscope configured with an adaptive illumination device, in accordance with one embodiment.

FIG. 3 illustrates a first arrangement of components of an optical light microscope having an adaptive illumination device, in accordance with one embodiment.

FIG. 4 illustrates a second arrangement of components of an optical light microscope having an adaptive illumination device, in accordance with one embodiment.

FIG. 5 illustrates illumination of a sample observed by an optical light microscope, in accordance with one embodiment.

FIG. 6 illustrates an adjustment to the illumination of the sample of FIG. 3 provided by an adaptive illumination device, in accordance with one embodiment.

FIG. 7 illustrates a first example of an adaptive illumination device, in accordance with one embodiment.

FIG. 8 illustrates a second example of an adaptive illumination device, in accordance with one embodiment.

FIG. 9 illustrates a method of adjusting illumination of a sample during image acquisition using a CPDB-iOLM system configured with an adaptive illumination device, in accordance with one embodiment.

FIG. 10 illustrates a simplified diagram of a representative CPDB-iOLM system configured with an adaptive illumination device, in accordance with one embodiment.

FIG. 11 illustrates a control system used to operate a CPDB-iOLM system configured with an adaptive illumination device, in accordance with one embodiment.

### DETAILED DESCRIPTION

A charged particle dual beam (CPDB) system may be utilized as a platform for obtaining lamellae from samples, where one or more regions of interest (ROIs) within the lamella can be observed using transmission electron microscope (TEM) imaging. As an example, the CPDB system may be a focused ion beam-scanning electron microscope (FIB-SEM) system that applies an ion beam to a sample based on images obtained by probing the sample with an electron beam. The ion beam may mill the sample around a ROI identified in the SEM images to form a lamella that is sufficiently thin (e.g., <200 nm) for images of the ROI to be acquired via a TEM.

In some instances, such as when TEM images of biological specimens are to be obtained, illumination of a specimen with specific wavelengths may cause excitation of certain molecules be allow specific structures in the specimen to be visually identified, such as cells and tissues. For example, the specimen may be fluorescently labeled (e.g., with fluorophores) and illuminating the specimen to induce fluorescence may allow target biological structures to be readily observed. Such illumination may be achieved using an optical light microscope, such as a fluorescence light microscope. In at least one embodiment, the optical light microscope is a wide-field fluorescence light microscope that illuminates an entire FOV at once using a broad light source and the illuminated area is captured in an image using a camera. In at least one example, the fluorescence light microscope may be an in-chamber or integrative fluorescence light microscope, where the fluorescence light microscope may be integrated into the FIB-SEM system such that fluorescence images and SEM images of a sample and application of an ion beam to the sample may be performed without demanding removal or transfer of the specimen from a sample chamber.

Analysis of a sample using an optical light microscope to identify one or more ROIs may be performed by first obtaining low resolution overviews covering a large area of the sample, followed by acquisition of local high resolution image stacks using a highest possible resolution of the optical light microscope. For example, the low resolution overviews may be 2D overviews collected from a 1-2 mm total field of view (FOV), while the high resolution image stacks may be 3D image stacks collected from a 100-150 μm FOV. As such, to obtain the low resolution overviews, a microscope objective that allows for a large FOV may be used, which may be associated with relatively low magnification of the sample. For the high resolution image stacks, an objective with a highest numerical aperture (N/A) possible relative to a working distance (WD) and objective shape constraints of the microscope may be used.

To satisfy requirements for acquiring 2D overview and 3D image stacks, individual objectives for each image acquisition type may be demanded. However, in CPDB systems having an integrated optical light microscope, an amount of space (e.g., a packaging space) within a sample holder, to which each of the FIB column, SEM column, and optical light microscope is coupled, may not accommodate more than one microscope objective. For example, the sample may be placed in a vacuum chamber into which an end of each of the FIB column and the SEM column extends. The FIB column and the SEM column may be angled such that a focal point/FOV of the FIB column overlaps or coincides with a focal point/FOV of the SEM column at a eucentric point. Within the vacuum chamber, a positioning of the FIB column and the SEM column with respect to the sample may result in a remaining amount of space above the sample to allow only one objective to be used. A configuration of the integrated optical light microscope may be therefore constrained to a single objective to acquire both 2D overviews and 3D image stacks. In addition, a WD of the objective of greater than 1 mm may be demanded to circumvent obtrusion by the objective of ion and electron beams generated by the FIB and SEM, respectively.

The issues described above may be addressed, at least in part, by implementing an optical light microscope system having an objective with operational parameters that achieves both low resolution, wide field imaging and local, high resolution imaging when used in conjunction with on-chip camera cropping and binning. In other words, a single objective may acquire both 2D overview and 3D image stacks by utilizing virtual magnification. In at least one example, virtual magnification may include using software (e.g., algorithms, code, etc.) to magnify a portion of an acquired image. As an example, the optical light microscope system may include an objective providing 20× magnification, a N/A of 0.7, and a WD of 1.3 mm. The optical light microscope may further include a camera chip with a resolution of 4000 pixels in width×4000 pixels in height.

Virtual magnification of a low resolution optical light microscope image, such as a 2D overview, may include adjusting an imaging area (e.g., cropping) based on an acquired image and adjusting how values of neighboring pixels are combined into a single pixel (e.g., binning). In at least one example, a portion of an image may be virtually magnified by increasing cropping of the image and decreasing binning of the image pixels. Exemplary virtual magnification parameters are shown below in Table 1 for a complementary metal-oxide semiconductor (CMOS) camera with 4000×4000 pixel resolution.

TABLE 1
Exemplary virtual magnification parameters
for 20x, 40x, and 80x magnifications.

| | 20x | 40x | 80x |
|---|---|---|---|
| FOV (μm) | 500 × 500 | 250 × 250 | 125 × 125 |
| Binning | 4 | 2 | 1 |
| Pixel size (nm) | 500 | 250 | 125 |
| Pixels | 1000 × 1000 | 1000 × 1000 | 1000 × 1000 |
| Illumination time | 20 | 80 | 320 |
| (ms) | | | |

While virtual magnification of an imaging region may be applied to an image captured by an optical light microscope system to obviate a dependency on more than one objective, an area of a sample illuminated by the microscope's light source may remain fixed despite changes to the optical light microscope's FOV. For example, regardless of how a portion of an image observed via the optical light microscope may be magnified virtually, the illuminated area of the image may be invariant. As an example, using values shown above in Table 1, an initial image captured by a fluorescence light microscope system at 20× magnification may correspond to a FOV of 500 μm×500 μm and an illuminated area of the sample of 520 μm×520 μm.

A portion of the initial image may be magnified further to 80×, thereby decreasing the FOV to 125 μm×125 μm. The illuminated area of the sample is still 520 μm×520 μm even though only 6.25% of the illuminated area is actually depicted in the FOV. As a result, illuminated areas of the sample that are outside of the FOV of the fluorescence light microscope may be exposed to irradiation over prolonged durations of time while high resolution images are being acquired. In some instances, the illuminated areas outside of the FOV may include additional ROIs that may become degraded before the ROIs can be further observed and/or analyzed. Furthermore, light exposure, as measured in photons/μm², may increase quadratically with virtual magnification due to an increased number of pixels per area to receive a target quantity of photons that yields a high quality image. Increasing exposure of the sample to light may cause, in some examples, warming and bleaching of the sample.

In at least some examples, the vacuum chamber of the CPDB system may maintain a cryogenic environment. For example, the sample may be a vitrified biological specimen and exposure of the sample to light, even within the cryogenically cooled conditions of the vacuum chamber, may cause devitrification of the sample. Prolonged light exposure may also cause bleaching, generation of free radicals, and/or sublimation of water via localized heating. In addition, loss of sample integrity in regions outside of the FOV of the optical light microscope may not be observed until after image acquisition is complete because the over exposed regions are not visible in the FOV. As a result, a user may not be aware of sample degradation until an image acquisition session is complete.

In at least one embodiment, as described herein, superfluous exposure of a sample may be mitigated via an adaptive illumination device. For example, the sample may be analyzed via a CPDB system having an in-chamber (e.g., integrated) optical light microscope system where each of an ion beam column, an electron beam column, and an optical light microscope may be coupled to a vacuum chamber in which the sample may be placed for imaging and analysis. The adaptive illumination device may be included in the optical light microscope to dynamically adjust irradiation of the sample by a light emitted from a light source of the optical light microscope. For example, a boundary of an illuminated area of the sample may be varied based on virtual magnification of an area within a FOV of the optical light microscope. If the FOV is decreased in order to increase virtual magnification, the adaptive illumination device may be used to correspondingly decrease dimensions (e.g., along a plane perpendicular to a beam axis between a sample and a camera of the microscope) of the illuminated area. The illuminated area may thereby match, or at least be similar to, the FOV of the optical light microscope. As an example, the illuminated area may be between an area of the FOV of the optical light microscope and 10% larger than the area of the FOV. As another example, the illuminated area may be between an area of the FOV and 20% larger than the area of the FOV.

The adaptive illumination device may be, for example, a programmable mask or field stop that is positioned in an illumination beam path of the optical light microscope. In one example, the adaptive illumination device may be a motorized field stop, which may include an aperture or diaphragm that can be adjusted by a motor. In another example, the adaptive illumination device may be a spatial light modulator (SLM), which can utilize liquid crystal materials to modulate light, used in combination with charge-coupled device (CCD) technology. In yet another example, the adaptive illumination device may be a digital light deflector (DLD), or a digital micromirror device (DMD), that utilizes microelectromechanical systems (MEMS) technology to deflect light.

In some instances, adaptive illumination can be applied to a confocal microscope system, such as a laser-scanning microscope. For example, adaptive illumination may refer to dynamic adjustment of illumination of a sample, which may or may not utilize a specific device to perform the adjustment. Because the laser-scanning microscope uses a focused laser beam to scan a specimen point by point, or line by line, illumination of regions that are not observed in images is largely circumvented except during certain events. For example, during scan phases where the laser beam is to be repositioned, e.g., transitioning from an end of one scan-line to a start of the next scan-line, deactivation of the laser beam is desirable to mitigate superfluous exposure of the sample to the laser beam. In some examples, the laser beam can be switched off with milli- or microsecond precision, thereby facilitating adaptive illumination. However, this corresponds to deactivating the laser beam entirely, rather than modifying a light beam such that a portion of the sample can remain illuminated while unobserved portions are not. Moreover, for some laser-scanning microscopes, such high precision deactivation is not achievable. In such instances, implementing an adaptive illumination device, as described herein, at an intermediate image plane of the microscope (e.g., between a scan generator and a light microscope objective) may reduce needless light exposure of a sample.

As an exemplary use-case scenario, a CPDB system with an integrative OLM (e.g., a CPDB-iOLM system) may be configured to at least acquire images of a cryogenically-maintained sample to determine milling of lamellae for subsequent TEM analysis. The OLM is a fluorescence light microscope system, such as a wide-field fluorescence light microscope system. In such an example, the sample includes a specimen support structure supporting a specimen, where the specimen may be, for example, a solution of cells, a piece of tissue, etc. The specimen support structure may have a variety of arrangements but, regardless of specific configuration, is used as a medium on which a specimen may be placed during analysis. In particular, for non-rigid samples, such as solutions and organic matter, the specimen support structure allows such samples to be handled without loss of sample or loss of integrity of the sample.

As one example, the specimen support structure may be a grid having a rigid outer frame surrounding a central region formed of a mesh. A film, such as a holey carbon film (although other types of films are possible), may be laid over the mesh and biological cells can be seeded, or a piece of tissue may be placed, on the film. The resulting sample can be gripped by a sample carrier, such as tweezers, along the rigid outer frame. As another example, the specimen support structure may include more than one grid, which are stacked to enclose a specimen. For example, the specimen support structure may include two grids forming a sandwich on opposite sides of a piece of tissue. The grids may be clamped together by a rigid outer frame to form a unitary structure that can be manipulated by a sample carrier along the outer frame.

In at least one embodiment, such as when the sample includes a single grid with a specimen deposited thereon, cells of the specimen are labeled using at least one fluorescence dye to mark areas in the cells targeted for TEM tomographic analysis. The sample are vitrified and loaded into a vacuum chamber of the CPDB-iOLM system. In another embodiment, such as when the sample includes two or more stacked grids with a specimen deposited between at least two grids, the specimen may be a solution of cells or a piece of tissue. The specimen may be labeled and the sample may be vitrified, for example, in a high pressure-freezing device.

A first overview image using a SEM of the CPDB-iOLM system is acquired to select cells of the sample that are suitable for lamella milling. A second overview image (e.g., a 2D overview) is then captured at low resolution using the iOLM to identify which of the cells targeted for lamella milling are also fluorescently labeled. The iOLM is further used to acquire local high-resolution 3D image stacks for all cells of the sample and/or one 3D image stack per cell. During 3D image stack acquisition, a series of high-resolution 2D images are captured at different focal planes, and stacked to generate a 3D reconstruction. An adaptive illumination device of the iOLM may be used, e.g., as facilitated by a controller based on stored executable instructions, to automatically adjust illumination of the sample according to changes in virtual magnification of the sample. For example, as a user reduces a FOV of the iOLM objective to zoom in on a particular cell of the sample for 3D image stack acquisition thereof, the adaptive illuminative device may modulate a light beam of the iFLM such that an illuminated area of the sample is decreased according to a change in the FOV. In other words, a perimeter or boundary of the illuminated area is selectively varied (e.g., using a control system) such that regions of the sample that are outside of the FOV do not remain illuminated while the 3D image stack is obtained. A light dosage of unobserved regions of the sample is thereby minimized.

Information provided by the acquired 3D image stacks (e.g., fluorescence data) is used to target milling areas of the sample, the target milling areas adjacent to labeled structures of interest, so that the structures are centered within milled lamellae. Another 3D image stack is obtained for each lamella to verify that a labeled structure is within the respective lamella. In some instances, acquisition of 3D image stacks may be performed multiple times throughout the use-case scenario describe above, such as before milling, after coarse milling, after fine milling, and after final polishing. Implementation of the adaptive illumination device may therefore have a pronounced effect on reducing sample degradation during iterative imaging and milling workflows. Moreover, modulation of light provided by an in-chamber optical light microscope system, as opposed to separate, external optical light microscope system used in conjunction with a CPDB system, obviates transfer of a sample between the systems. This reduces a likelihood of sample warming, ice formation, and/or contamination, and streamlines associated workflows.

Incorporation of an adaptive illumination device into a CPDB system utilizing an OLM may therefore provide the technical effect of selectively moderating illumination of a sample to minimize degradation of the sample due to light exposure. As a result, an integrity of the sample is maintained over longer durations of time, allowing a greater amount of data to be collected from the sample. The greater data collection allows lamellae to be formed, e.g., by FIB milling, that capture target ROIs with greater precision. In addition, the adaptive illumination device may be retrofit to already existing systems, which may maintain costs low. The systems and methods described herein with respect to implementation of the adaptive illumination device thereby address the aforementioned issue of sample degradation during image acquisition in an efficient and effective manner.

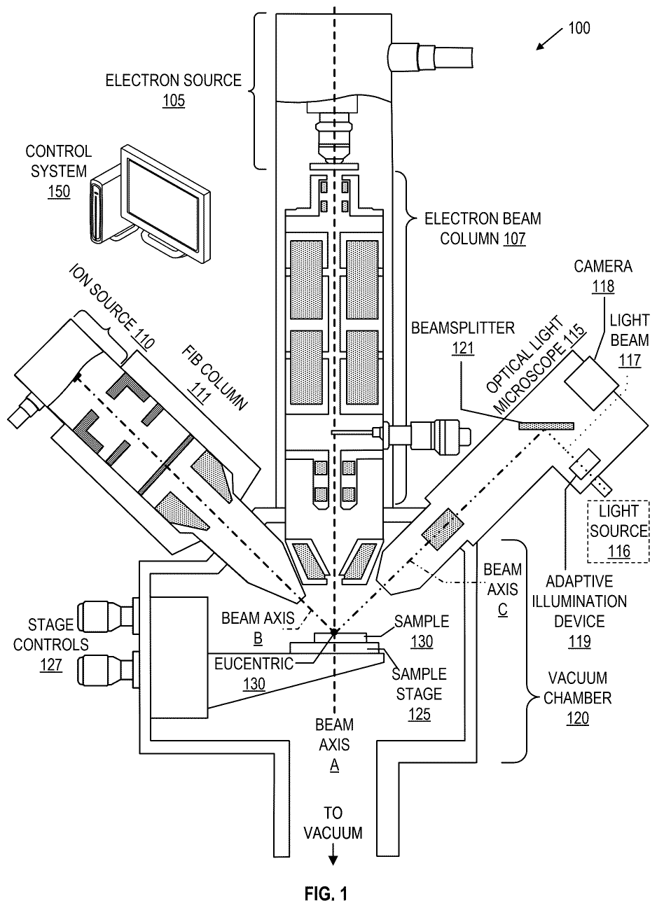

FIG. 1 is a schematic diagram illustrating an example CPDB system having an integrative optical light microscope system, hereafter referred to as a CPDB-iOLM system 100, in accordance with some embodiments of the present disclosure. The example system 100 includes an electron source 105, an electron beam column 107, an ion source 110, a focused ion beam (“FIB”) column 111, an optical light microscope (OLM) 115, a vacuum chamber 120, and a sample stage 125. The vacuum chamber 120 surrounds the sample stage 125, and a sample 130 placed thereon, such that the sample 130 is enclosed by the vacuum chamber 120. The electron beam column 107 is illustrated as a SEM column, such that the example system 100 includes a dual beam FIB-SEM system. The electron beam column 107, the FIB column 111, and the OLM 115 are illustrated as being operably coupled with the vacuum chamber 120, with the electron beam column 107 defining a first beam axis A, the FIB column 111 defining a second beam axis B, and the OLM 115 defining a third beam axis C. The axes A, B, and C are illustrated converging onto a region of the sample 130 at a eucentric point 103. For example, focal points of the FIB column 111, the electron beam column 107, and the OLM 115 coincide and overlap on the sample 130 at the eucentric point 103. A FOV of the OLM 115 is thereby aligned with focal points of the FIB column 111 and the electron beam column 107. In other words, an image of the sample 130 acquired from the FOV of the OLM 115 can be superimposed on data collected using the electron beam column 107 and the FIB column 111. Advantageously, while axes A, B, and C can also be oriented toward different locations, convergence permits the SEM system to image the region of the sample also being imaged by the OLM 115 and processed by the FIB. For example, in some embodiments, axes A and B converge at the eucentric point 103 but axis C is offset from axes A and B. The sample stage 125 travels along a fixed, known distance and angle between the eucentric point 103 and the FOV corresponding to axis C. The known distance and angle can be used to precisely overlay images obtained by the CPDB and the OLM.

In yet other embodiments, the focal points of the FIB column, the electron beam column 107, and the OLM 115 do not converge at the eucentric point 103. For example, axes A, B, and C may have focal points along a sample at different regions of the sample. Moreover, the focal points may not overlap. However, offsets and/or distances between the focal points may be determined and used to correlate and superimpose data obtained by the FIB column, the electron beam column 107, and the OLM 115.

The electron source 105 can include one or more emitters configured to generate electrons and to direct the electrons into the electron beam column 107. The emitters can include thermionic emitters, Schottky emitters, field-emission source emitters, or combinations thereof, operably coupled to power systems configured to apply a high-voltage (e.g., on the order of kilovolts to hundreds of kilovolts) to an emission region of the emitter material. For example, the electron source 105 can include a lanthanum hexaboride (LaB₆) emitter crystal to which a high electrical potential is applied to elicit the emission of electrons from a tip of the emitter crystal. In this way, a beam of electrons can be directed into the electron beam column. The electron beam column 107 includes electromagnetic optics (e.g., electrostatic lenses, electromagnetic lenses, monochromators, etc.) and apertures configured to shape, focus, defocus, and direct the beam of electrons such that the beam is focused onto the sample 130, in accordance with a set of operating parameters. The operating parameters can include a beam current, a beam energy (e.g., in volts, in electron volts, or the like), a magnification parameter, a scan pattern, a dwell time, and/or one or more pulse parameters. In at least one example, the beam energy can be from about 1 keV to about 50 keV. In this way, the example system 100 can function as an SEM to image portions of the sample 130.

The ion source 110 can include one or more components configured to generate a beam of ions and to direct the ions into the FIB column 111. The ions can include metal ions and/or nonmetal ions (e.g., noble gas, halogen, oxygen, nitrogen, or the like). To that end, the ion source 110 can include a plasma source (e.g., an inductively coupled plasma source) and/or a metal ion source (e.g., a liquid-metal ion source). As with the electron beam column 107, the FIB column can include electromagnetic optics (e.g., electrostatic lenses, electromagnetic lenses, monochromators, etc.) and apertures configured to shape, focus, defocus, and direct the beam of ion such that the beam is focused onto the sample 130, in accordance with a set of operating parameters. The operating parameters can include a beam current, a beam energy (e.g., in volts, in electron volts, or the like), a magnification parameter, a scan pattern, a dwell time, and/or one or more pulse parameters. In this way, the example system 100 can function as a FIB to remove portions of the sample 130.

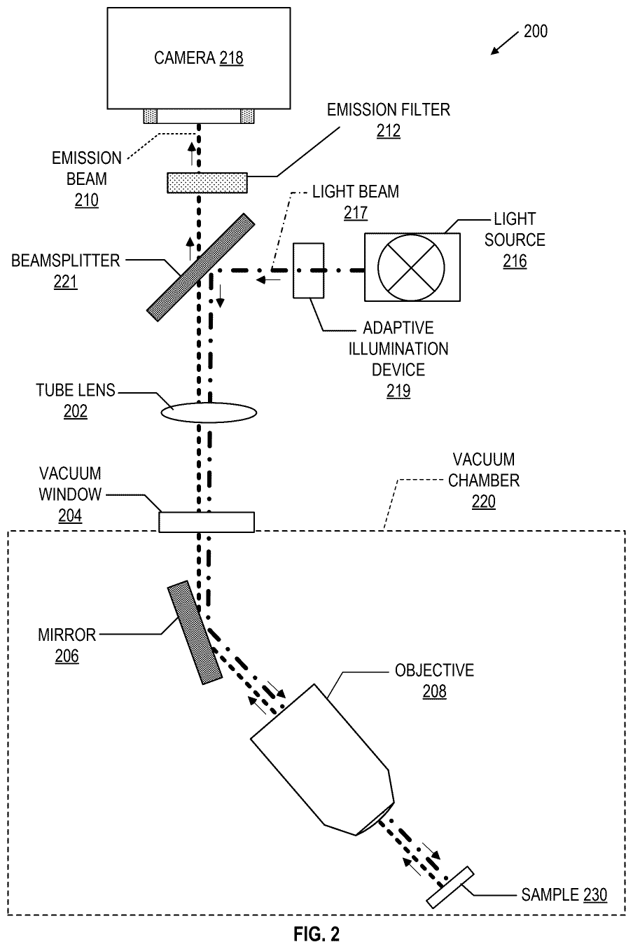

The OLM 115 can include a plurality of internal components (as shown in FIGS. 2-4 and described below) to direct a light beam 117 from a light source 116 to the vacuum chamber 120 along the beam axis C. The light source 116 may be, for example, a broad light source, such as a light-emitting diode (LED), a halogen lamp, a xenon lamp, a mercury arc lamp, etc. The light beam 117 is guided through the OLM 115 to illuminate the sample 130 for image acquisition by a camera 118 of the OLM 115. In at least one embodiment, the OLM 115 is a fluorescence light microscope and the light source 116 is configured to generate the light beam 117 at wavelengths that induce fluorescence in fluorescently labeled specimens, which can be observed in images acquired by the camera 118. In other embodiments, the OLM 115 is any of a variety of types of microscopes including, but not limited to, confocal microscopes, polarized light microscopes, phase-contrast microscopes, dark-field microscopes, among others.

An adaptive illumination device 119 is arranged in the OLM 115 in a path of the light beam 117. As described above, the adaptive illumination device 119 may be a motorized field stop, a SLM, a DLD, DMD, or some other type of mechanism that can modulate and adjust illumination of the sample 130 by the light beam 117. Furthermore, the adaptive illumination device 119 is controllable by control circuitry, such as a control system 150 of the CPDB-iOLM system 100. In this way, the adaptive illumination device 119 can be used to dynamically adjust illumination of the sample 130 in an automated manner, in conjunction with image acquisition.

In one example, as shown in FIG. 1, the adaptive illumination device 119 is positioned generally in the OLM 115 downstream e.g., with respect to a direction of light propagation from the light source 116 to the sample 130, of the light source 116 and upstream of a beamsplitter 121. In at least one embodiment, the beamsplitter 121 is a dichroic mirror. In another embodiment, the beamsplitter 121 is a partially (e.g., half) transparent mirror that allows the OLM 115 to be operated in a reflective imaging mode. Moreover, the OLM 115 may be operated in any of a variety of operating modes, depending on a configuration of the OLM 115, including, but not limited to, a bright-field mode, a dark-field mode, a phase-contrast mode, a confocal mode, and a polarized light mode.

In yet other embodiments, the beamsplitter 121 is any other type of optical device that can split a beam of light into two or more separate beams. To moderate illumination of the sample 130, the adaptive illumination device 119 is arranged between the light source 116 and the sample 130 such that adjustments to the adaptive illumination device 119, e.g., as instructed by the control system 150, may continuously modify a cross-sectional area of the light beam 117 upstream of the sample 130. Although a placement of the adaptive illumination device 119 between the light source 116 and the beamsplitter 121, as illustrated in FIG. 1 may provide maximum accessibility and simplicity with respect to electronic controls, the placement of the adaptive illumination device 119 relative to internal components of the OLM 115 may vary depending on a type of the adaptive illumination device 119 and/or a specific configuration of the OLM 115, as described further below.

The operation of one or more components of the example system 100 can be coordinated by the control circuitry of the control system 150, in accordance with machine-executable instructions (e.g., software, firmware, etc.) that can be stored in machine-readable storage media and/or received from external systems via wired and/or wireless communication techniques (e.g., over a WiFi or Bluetooth link). To that end, components of the example system can be automated (e.g., operating without human intervention), pseudo-automated (e.g., operating with limited human intervention to initiate operations, analyze output and confirm, or the like), or manually operated (e.g., where individual operations of the example system 100 are performed by a human user). In an illustrative example, the sample stage 125 can be mechanically coupled with automated stage controls 127 that permit the sample 130 to be reversibly tilted relative to the beam axes A, B, and C, such that the surface of the sample is substantially normal to a given beam axis during operation of the corresponding charged particle or light beam source. In this way, the operation of a given beam source can be coordinated with the operation of the stage controls 127.

Embodiments of the present disclosure can omit one or more components of example system 100. For example, one or more of the sources 105 and 110 and/or columns 107 and 111 can be omitted. In an illustrative example, an SEM system can be configured to perform operations of the beam-induced deposition processes of the present disclosure. Similarly, a FIB system other than a dual-beam FIB-SEM (e.g., a FIB system for which two or more beam axes are not convergently trained on a given region of the sample 130) can include the OLM 115 oriented to be convergent with the first beam axis A and/or the second beam axis B.

Moreover, while the CPDB-iOLM system 100 is depicted in FIG. 1 having the FIB column 111, electron beam column 107, and OLM 115 coupled (e.g., each having at least a portion extending into the vacuum chamber 120 above the sample 130) to the vacuum chamber 120, additional components of the CPDB-iOLM system 100 can be coupled to the vacuum chamber but have been omitted from FIG. 1 for clarity. For example, the CPDB-iOLM system 100 can include one or more gas injection systems to facilitate deposition and/or removal of materials from a sample. In addition, the specific configuration of the CPDB-iOLM system 100 shown is non-limiting, and variations in the configuration are possible without departing from the scope of the present disclosure.

An OLM system 200 is illustrated in FIG. 2, which may be included in a CPDB-iOLM system, such as the CPDB-iOLM system 100 of FIG. 1. As an example, the OLM system 200 may be an embodiment of the OLM 115 shown in FIG. 1. The OLM system 200 may include a light source 216 that generates an incident light beam 217 to illuminate a sample 230. In at least one embodiment, the light source 216 may be a broad light source, such as an LED, that provides excitation light for fluorescence imaging. For example, the light source 216 may be a multi-channel LED light source that emits light as specific wavelengths to excite fluorescent and/or fluorescently tagged molecules of the sample 230. As such, the incident light beam 217 may be a beam of light formed of wavelengths that may be selected according to target ROIs of the sample 230. As an example, the incident light beam 217 may include one or more wavelengths corresponding to excitation of dyes used to promote and/or enhance fluorescence.

The incident light beam 217 may pass through an adaptive illumination device 219 arranged between the light source 216 and the sample 230. In one example, the adaptive illumination device 219 may be positioned such that an entire cross-sectional area of the incident light beam 217 passes through the adaptive illumination device 219 unless the adaptive illumination device 219 is selectively adjusted to constrain or vary how much of the cross-sectional area of the light beam 217 passes therethrough. Additionally or alternatively, the adaptive illumination device 219 may be used to modify an intensity of the incident light beam 217 when the incident light beam 217 illuminates the sample 230. For example, the adaptive illumination device 219 may decrease an intensity of the incident light beam 217 according to a specific pattern or geometric shape (with respect to the cross-sectional area of the light beam 217), and/or vary a phase or polarization of the incident light beam 217. As described above, the adaptive illumination device 219 may be adjusted, e.g., by a control system such as the control system 150 of FIG. 1 or manually, to modify illumination of the sample 230. For example, by adjusting an interaction of the adaptive illumination device 219 with the incident light beam 217, a boundary or perimeter of an area of the sample 230 that is irradiated by the incident light beam 217 may be increased, decreased, or otherwise altered.

Different locations of the adaptive illumination device 219 within the OLM system 200 are possible. In one example, as illustrated in FIG. 2, the adaptive illumination device 219 may be arranged in a first portion of a path of the incident light beam 217 between the light source 216 and a beamsplitter 221 (e.g., a dichroic mirror), where this first portion of the path may be oriented perpendicular to a subsequent, second portion of the path of the incident light beam 217 extending between the beamsplitter 221 and a second mirror 206. Furthermore, in at least one embodiment, the second portion of the path of the incident light beam 217 may be substantially parallel with the third beam axis C of FIG. 1. When positioned between the light source 216 and the beamsplitter 221, the adaptive illumination device 219 may be arranged at a variety of distances relative to these components. For example, the adaptive illumination device 219 may be positioned closer to the light source 216 than the beamsplitter 221, or closer to the beamsplitter 221 than the light source 216. As another example, the adaptive illumination device 219 may be directly coupled to the light source 216, e.g., to a lens or window of the light source 216.

In each of the aforementioned positions, the adaptive illumination device 219 may be located in a portion of the OLM system 200 that is external to (e.g., outside of) the vacuum chamber 220. Positioning the adaptive illumination device 219 external to the vacuum chamber 220 may allow the adaptive illumination device 219 to be accessed readily (e.g., for replacement, inspection, maintenance, etc.). In addition, positioning the adaptive illumination device 219 external to the vacuum chamber 220 may mitigate increased complexity of the OLM system 200 arising from incorporating additional electronics and hardware associated with the adaptive illumination device 219. As well, placing the adaptive illumination device 219 only in the path of the light beam 217 and not in the path of the emission beam 210 (such as between the light source 216 and the beamsplitter 221) may allow for more simple and efficient integration of the adaptive illumination device 219 into the OLM system 200. For example, the adaptive illumination device 219 may simply block light of any wavelength, rather than being configured to block wavelengths of the light beam 217 but transmit wavelengths of the emission beam 210. Moreover, arranging the adaptive illumination device 219 in a location between the light source 216 and the beamsplitter 221 may provide greatest accessibility and least modifications to the OLM system 200 when the adaptive illumination device 219 is retrofit to the OLM system 200.

Components of the OLM system 200 arranged in the path of the incident light beam 217 will now be described along a downstream direction (e.g., in a direction from the light source 216 to the sample 230, as indicated by arrows). The incident light beam 217 may be separated from the emission beam 210 at the beamsplitter 221. In one example, the paths of the emission beam 210 and the incident light beam 217 may converge between the beamsplitter 221 and the sample 230, where the emission beam 210 is formed of light emitted from the sample 230 to a camera 218 (as indicated by arrows). The beamsplitter 221 allows the emission beam 210 to pass therethrough while reflecting the incident light beam 217 in a direction that guides the incident light beam 217 to the sample 230. For example, fluorescent light emitted by the sample 230 to form the emission beam 210 may include different wavelengths than the light wavelengths of the incident light beam 217 used to excite fluorophores of the sample 230. Therefore, the beamsplitter 221 may be configured to be transparent to the wavelengths of the emission beam 210 but operate as a mirror to reflect the wavelengths of the incident light beam 217.

The beamsplitter 221 may be oriented to reflect the incident light beam 217 at an angle relative to a direction of the incident light beam 217 when emitted from the light source 216. For example, as shown in FIG. 2, the light source 216 may be positioned relative to an axis of the OLM system 200, the axis being parallel with the emission beam 210, such that the incident light beam 217 is to be deflected by 90 degrees, although other angles are possible. The beamsplitter 221 may therefore be oriented at 45 degrees relative to the direction of the incident light beam 217 when emitted from the light source 216.

Upon deflection at the beamsplitter 221, the incident light beam 217 may pass through the tube lens 202, which may either not modify the incident light beam 217 or may focus the incident light beam 217, and enter the vacuum chamber 220 through the vacuum window 204. The vacuum window 204 may be an optical interface that can maintain a low pressure environment within the vacuum chamber 220 while allowing the incident light beam 217 (and the emission beam 210) to pass through. The second mirror 206 may also be located within the vacuum chamber 220. The incident light beam 217 (as well as the emission beam 210) may be deflected by the second mirror 206 which causes the incident light beam 217 to pass through the objective 208 and illuminate the sample 230.

Illumination of the sample 230 may excite molecules of the sample 230 and induce fluorescence thereof. Fluorescence of the fluorophores of the sample 230 at specific wavelengths (e.g., at longer wavelengths than those of the incident light beam 217) may be emitted as the emission beam 210, which may be collected and focused by the objective 208 to form an image of the sample 230. For example, the objective 208 may produce a primary magnification of the sample 230. The objective 208 may have a specific configuration (e.g., geometry, hardware, operating parameters, etc.) that allows the objective 208 to achieve a target magnification and resolution of the image. In one example, the objective 208 may provide 20× magnification, a N/A of 0.7, and a WD of 1.3 mm. In another example, the objective 208 may be a piezo-driven objective that relies on piezoelectric actuators to move the objective 208, although other types of objectives are possible. By implementing the objective 208 to be piezo-driven, rapid, precise, and automated adjustments to the objective 208 may be made while mechanical drift may be reduced.

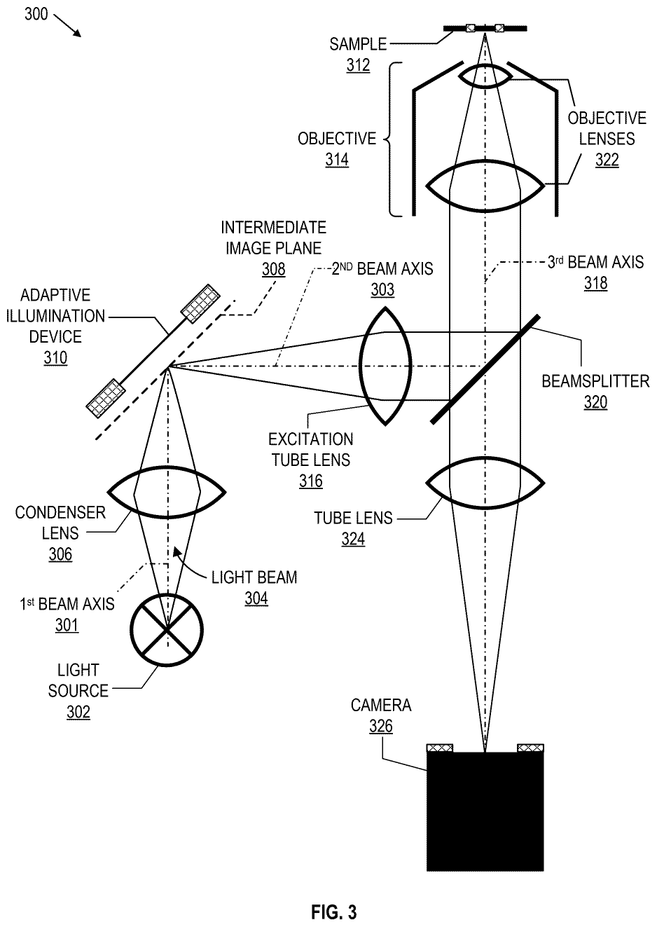

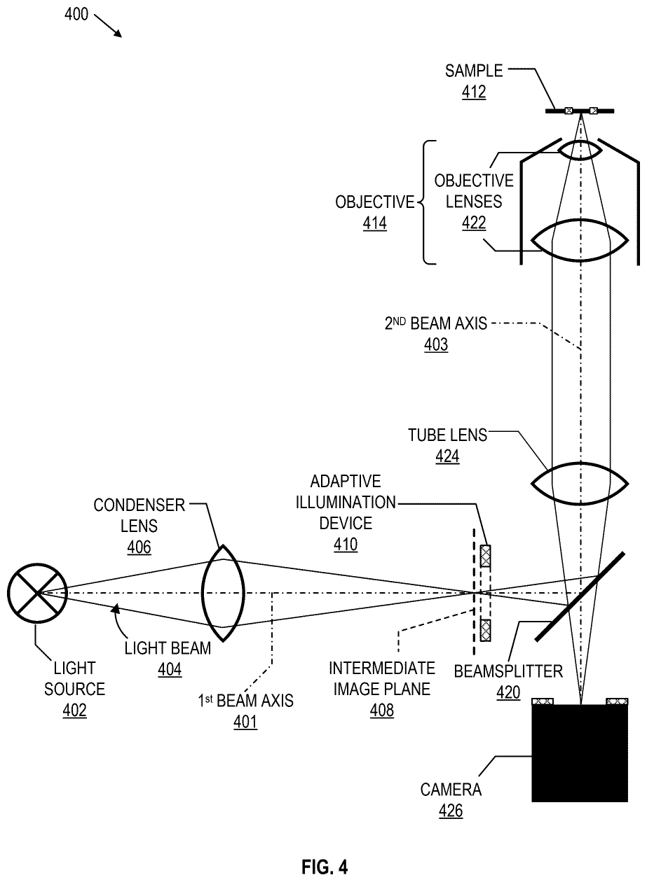

The emission beam 210 may be deflected by the second mirror 206 to pass through the vacuum window 204 to be received at the tube lens 202. The tube lens 202 may focus the emission beam 210 to assist in forming a magnified image at an image plane (e.g., an intermediate image plane as shown in FIGS. 3 and 4 and discussed below). Optical aberrations, such as chromatic aberrations, may be reduced or minimized by the tube lens 202.

The emission beam 210 may then pass through the beamsplitter 221 to be filtered at an emission filter 212. The emission filter 212 may selectively transmit target wavelengths that are emitted by the sample 230 and simultaneously block undesirable wavelengths. For example, the undesirable wavelengths may be wavelengths that are not to be detected by the camera 218, or may be wavelengths that may interfere with detection of the target fluorescence wavelengths.

The target fluorescence wavelengths may be received at the camera 218 from the emission filter 212. The camera 218 may have, for example, suitable sensitivity to detect fluorescence emitted by the sample 230 and be configured to minimize noise, such as thermal noise. Furthermore, the camera 128 may be selected to have a target FOV, dynamic range, frame rate, bit depth, etc. In at least one example, the camera 218 may have a resolution that provides a pixel size in the range of 100-130 nm at system magnification. In one example, the camera 218 may be a CMOS camera with a 4K resolutionand a 2.74 μm pixel size.

Embodiments of an OLM having an adaptive illumination device to moderate illumination of a sample in a CPDB-iOLM system are illustrated in FIGS. 3 and 4. The embodiments of FIGS. 3 and 4 depict specific arrangements of OLM components, which may be incorporated into, for example, the OLM system 200 of FIG. 2 and the CPDB-iOLM system 100 of FIG. 1. A first embodiment of an OLM 300 is shown in FIG. 3 that includes a light source 302, which may be, for example, an LED light source or some other type of light emitting device. The light source generates a light beam 304 which passes through a condenser lens 306. In one example, the condenser lens 306 focuses and causes the light beam 304 to converge at an intermediate image plane 308 of the OLM 300. The intermediate image plane 308 is a location at which an initial image of a sample 312 is formed by an objective 314 of the OLM 300, where the initial image may be further magnified as requested by a user.

An adaptive illumination device 310 is positioned proximate to the intermediate image plane 308. Although depicted in FIG. 3 as being behind the intermediate image plane 308, with respect to transmission of the light beam 304 from the light source 302, in other examples, the adaptive illumination device 310 may instead be positioned in front of the intermediate image plane 308. The adaptive illumination device 310, as described above, may be any of a motorized field stop, a SLM, a DLD, DMD, or some other type of mechanism that can modulate and adjust a cross-sectional area, a cross-sectional geometry, a cross-sectional intensity, a pattern, a phase, and/or a polarization of the light beam 304. While the adaptive illumination device 310 is arranged near the intermediate image plane 308, the adaptive illumination device 310 is not positioned within a plane of the intermediate image plane 308 to circumvent observation of sharp mirror edges in images acquired by the OLM 300 of the sample 312.

The adaptive illumination device 310 is oriented at an angle relative to a first beam axis 301 of the light beam 304 extending between the light source 302 and the adaptive illumination device 310. This causes the light beam 304 to be deflected at the adaptive illumination device 310 such the light beam 304 is transmitted along a second beam axis 303 that is perpendicular to the first beam axis 301. Upon reflection and modification at the adaptive illumination device 310, the light beam 304 passes through an excitation tube lens 316. The excitation tube lens 316 may focus the light beam 304 along the second beam axis 303 and filter the light beam 304 such that only target wavelengths reach the sample 312.

The light beam 304, upon exiting the excitation tube lens 316, is deflected by a beamsplitter 320 to be redirected along a third beam axis 305 that is perpendicular to the second beam axis 303 and parallel to the first beam axis 301. The light beam 304 may be focused by objective lenses 322 of the objective 314 and directed to the sample 312. The sample 312 is thereby illuminated by the light beam 304, which may be selectively modified by the adaptive illumination device 310. Light emitted by the sample 312, e.g., fluorescence, is transmitted along the third beam axis 305 from the sample 312, through the objective 314 to be defected by and/or transmitted through the beamsplitter 320. For example, at least a portion of the emitted light may be reflected along the second beam axis 303 to the intermediate image plane 308 (e.g., to form the initial image) and at least a portion of the emitted light may pass, along the third beam axis 305, through the beamsplitter 320 and a tube lens 324 to be received at a camera 326.

A second embodiment of an OLM 400 is shown in FIG. 4. The OLM 400 is depicted with components that are in common with those of the OLM 300 of FIG. 3 and will not be described in detail for brevity. The OLM 400 includes a light source 402 that emits a light beam 404 along a first beam axis 401. The light beam 404 passes through a condenser lens 406 which causes the light beam 404 to converge at an intermediate image plane 408.

An adaptive illumination device 410 is positioned proximate to the intermediate image plane to modify the light beam 404 when instructed to do so (e.g., by a control system). The light beam 404, upon passing through the adaptive illumination device 410, is deflected by a beamsplitter 420 along a second beam axis 403 that is perpendicular to the first beam axis 401. The light beam 404 is transmitted through a tube lens 424, and objective lenses 422 of an objective 414 to illuminate a sample 412.

At least a portion of light emitted by the sample 412 (e.g., fluorescence) is modified by the tube lens 424, passes through the beamsplitter 420 to converge at and be received by a camera 426. In addition, at least a portion of the light emitted by the sample 412 may be reflected by the beamsplitter 320 to converge at the intermediate image plane 408 (e.g., to form the initial image).

An adaptive illumination device may thereby be positioned in an OLM to enhance sample analysis and imaging. By including the adaptive illumination device in the OLM, at a location in the OLM that may vary based on a particular configuration of the OLM, illumination of a sample can be dynamically adjusted to reduce overall exposure of the sample to light that may otherwise degrade the sample. For example, the adaptive illumination device may modify a cross-sectional area of a beam of light from a light source to adjust how much of an area of the sample is illuminated by the beam of light. Light exposure of areas outside of a ROI of the sample may thereby be minimized. in a manner that can be customized according to a particular arrangement and geometry of the OLM. Incorporation of the adaptive illumination device the OLM may preserve sample integrity such that image acquisition and analysis can be performed over longer periods of time. As a result, a greater amount of information may be collected from a sample.

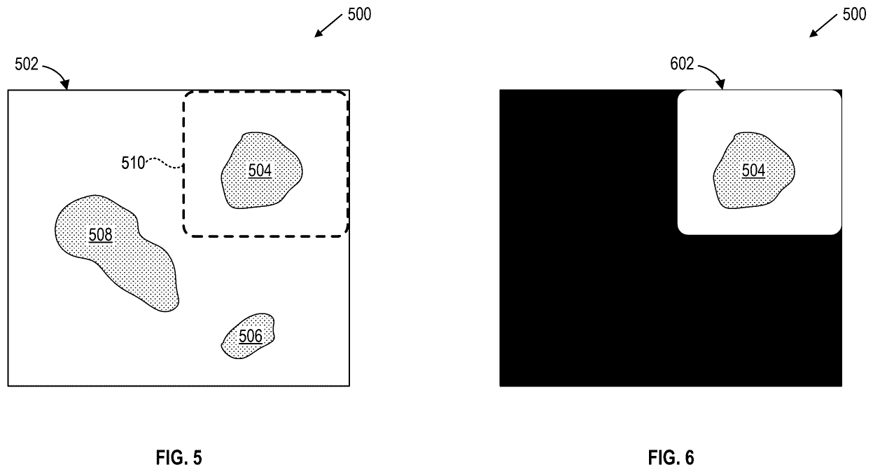

In at least one embodiment, the adaptive illumination device may be used to interact with a light beam in response to an indication that a portion of an image captured by an OLM is to be magnified. Upon determination that a portion of the image is to be magnified, illumination of the device may be constrained, using the adaptive illumination device, to correspond to the magnified portion. Exemplary illustrations depicting modified illumination of a sample, as facilitated by an adaptive illumination device, are shown in FIGS. 5 and 6.

As illustrated in FIG. 5, a sample 500 may be analyzed by a CPDB-iOLM system, such as the CPDB-iOLM system 100 of FIG. 1, having an adaptive illumination device, such as the adaptive illumination device 119 of FIG. 1 or 219 of FIG. 2. The sample 500 may be positioned within a vacuum chamber of the CPDB-iOLM system. As an example, sample 500 may be a vitrified cryogenic sample and the vacuum chamber may maintain a cryogenic environment. A first illuminated area 502 of the sample 500 includes a first ROI 504, a second ROI 506, and a third ROI 508. The first illuminated area 502 corresponds to a first FOV of the OLM and a first magnified view of the sample 500. For example, the iOLM may utilize a 20× objective and the first illuminated area 502 may be associated with a first image depicting a first portion of the sample 500 that is magnified by 20×.

A request for greater magnification of a second portion of the sample 500 may be received by a control system of the CPDB-iOLM system. In one example, a user may determine that greater magnification of the first ROI 504 is desired and may draw or place a dashed box 510 on the first image around the first ROI. The user may further select, e.g., via a menu or some other software-implemented mechanism, a magnification value that is greater than the magnification provided by the first image, such as 40× or 80×, for example. The control system may receive the request from the user and cause the area within the dashed box 510 to be virtually magnified.

The adaptive illumination device may be automatically adjusted to reduce the illuminated area of the sample 500 to a second illuminated area 602, as shown in FIG. 6, where the second illuminated area 602 is smaller in size than the illuminated area 502 and overlaps with the first illuminated area 502. In other words, the second illuminated area 602 is a sub-area of the first illuminated area 502. The second illuminated area 602 may correspond to a second FOV of the OLM that is virtually modified relative to the first FOV. Furthermore, the second illuminated area 602 is associate with (e.g., matches) an area indicated by the dashed box 510 of FIG. 5. A remaining portion of the area corresponding to the first illuminated area 502 of FIG. 5 and outside of the virtual FOV of the OLM is not illuminated (e.g., shown as black). In other examples, the remaining portion of the area that is outside of the virtual FOV may remain illuminated but to a lesser degree than the second illuminated area 602. A perimeter or boundary of the illuminated region of the sample 500 is thus adjusted to decrease an area (e.g., along a plane of the sample 500) of the illuminated region. In some examples, once image acquisition from the second FOV is complete, virtual magnification and image acquisition at a different region of the sample 500, such as at the second ROI 506 or the third ROI 508, may be performed in conjunction with application of the adaptive illumination device.

Mitigation of undesirable illumination of sample regions outside of a FOV (including a virtually modified FOV) of an OLM may have a pronounced effect on sample integrity during acquisition of 3D image stacks of a sample. For example, an acquisition time demanded to obtain a 3D image stack of an ROI of a sample may be longer than an acquisition time to obtain 2D overviews of the sample. As a result, a likelihood of sample degradation due to light exposure may be greater during 3D image stack acquisition. Implementing dynamic adaptive illumination during 3D image stack acquisition may therefore contribute to sample preservation and more complete and thorough data collection.

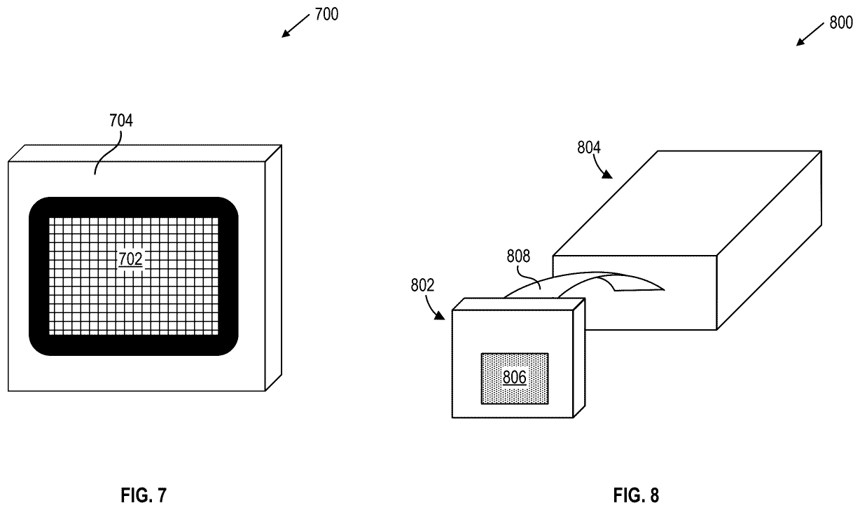

A first example of an adaptive illumination device which can be used in a CPDB-iOLM system is illustrated in FIG. 7. The adaptive illumination device is a DMD 700 having an array of mirrors 702 arranged in a central region of a front-facing surface of the DMD 700. The array of mirrors 702 is mounted on a substrate, such as a CMOS substrate, that allows a position of each mirror to be electronically adjusted. The array of mirrors 702 is surrounded by a rigid frame 704, which may be formed of a metallic material such as aluminum. When positioned in a path of a light beam, the mirrors of the array of mirrors 702 may be individually adjusted to modify a cross-sectional geometry of the light beam. The light beam may therefore have a different illumination capacity after interaction with the DMD 700 relative to the light beam prior to the interaction. For example, a cross-sectional area of the light beam or a shape of the light beam may be altered by the DMD 700.

A second example of an adaptive illumination device which can be used in a CPDB-iOLM system is illustrated in FIG. 8. The adaptive illumination device is a SLM 800, having a light-interactive portion 802 and an electronic circuitry portion 804. The light-interactive portion 802 has an active region 806 that can be implemented as various types of devices that deflect or otherwise interact with light. For example, the light-interactive portion 802 may be the DMD 700 of FIG. 7 and the active region 806 may be an array of mirrors. As other examples, the active region 806 may be configured with liquid crystals, MEMs, or may be electro-optic or magneto-optic. When positioned in a path of a light beam, the light-interactive portion 802 can modulate an intensity, phase, and/or polarization of the light beam.

The light-interactive portion 802 is coupled to the electronic circuitry portion 804 by one or more electrical connectors 808. The electronic circuitry portion 804 may include various electronic circuits and components to actuate and control the light-interactive portion 802. Furthermore, the electronic circuitry portion 804 may be electronically coupled to a control system of the CPDB-iOLM system to transmit and receive electronic signals to and from the CPDB-iOLM system.

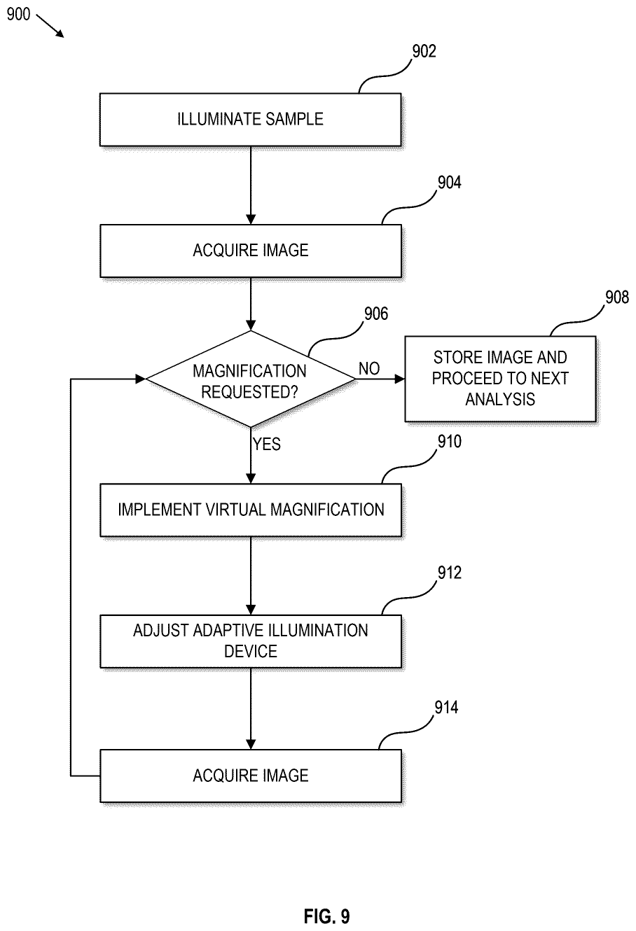

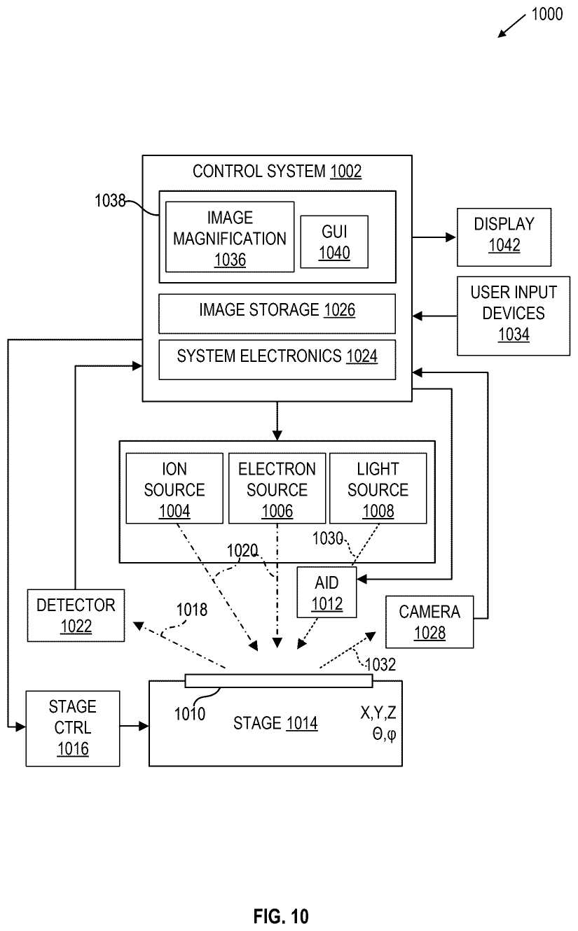

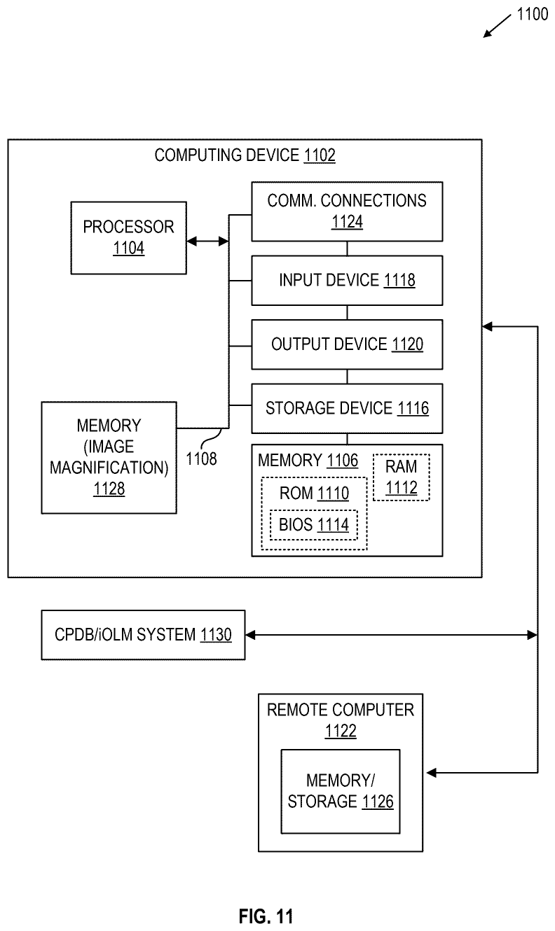

An example of a method 900 of dynamically adjusting illumination of a sample to analyzed and processed by a CPDB-iOLM system is shown in FIG. 9. In one example, the CPDB-iOLM system is the CPDB-iOLM system 100 of FIG. 1 and includes an adaptive illumination device. The adaptive illumination device may be any one of the adaptive illumination devices shown and/or described in conjunction with FIGS. 1-4, 7, and 8. The method 900 may be performed by a control system, such as the control system 150 of FIG. 1 or the control systems depicted in FIGS. 10 and 11 and described further below. The control system may include memory with executable instructions to cause one or more processors of the control system to provide instructions to actuatable components of the CPDB-iOLM system, including actuators of a SEM, a FIB, an OLM, and the adaptive illumination device, and to receive signals from components that are electronically coupled to the control system.

At 902, the method 900 includes illuminating the sample via a light source of the OLM. In at least one embodiment, the light source emits wavelengths that induce fluorescence of fluorophores in the sample. The adaptive illumination device is positioned in a path of a light beam generated by the light source but is in a first setting in which the adaptive illumination device does not modulate the light beam. As such an illuminated portion of the sample corresponds to a FOV of an objective of the OLM at a specified magnification of the objective. For example, the magnification may be 20×.

At 904, the method 900 includes acquiring one or more images of the illuminated portion of the sample. As an example, the one or more images may be 2D overviews of the sample to identify ROIs based on fluorescence of the sample. The one or more images may be obtained by a camera, such as a CMOS camera.

At 906, the method 900 includes determining if greater magnification of the sample is requested. For example, a user may identify a ROI from the 2D overviews and indicate that magnification of the ROI is desired. As an example, the user may indicate that a region of the sample corresponding to the ROI is to be magnified by drawing (e.g., using software implemented at a graphical user interface) an indicator, such as a geometric shape, around the ROI, highlighting the ROI, or some other technique for selecting a region in an image. The user may further indicate that 3D image stacks of the ROI are to be obtained.

If a request for increased magnification is not received, the method 900 includes proceeding to 908 to store the acquired images (e.g., in memory or at a database). The method 900 also includes proceeding to a next analytical step or process, such as scanning the sample using the SEM to acquire additional images, and/or applying the FIB to mill a lamella. As another example, the next analytical step or process may include obtaining images of a different portion of the sample or obtaining images of a different sample.

If a request for increased magnification is received, the method 900 includes continuing to 910 to implement virtual magnification of a portion of the sample. For example, the portion of the sample corresponding to the identified ROI may be magnification, as indicated by the user, by an amount specified by the user. As an example, the portion may be magnified 40×by binning image pixels within the portion of the sample and cropping a 2D overview image to the portion to produce an image with a magnified view of the portion that corresponds to a virtual FOV of the OLM. The portion of the sample for which virtual magnification is performed corresponds to a sub-area of an area of the sample that was previously illuminated prior to the increase in virtual magnification.

At 912, the method 900 includes adjusting the adaptive illumination device to modulate the light beam from the light source. The adjustment is implemented in response to request for increased magnification and may be performed in conjunction with virtual magnification of the sample. For example, the change to the virtual magnification of the portion of the sample may be identified and the adjustment may be performed based on the change to the virtual magnification and the corresponding change to the FOV of the OLM. In one example, the adjustment may be automatically and simultaneously performed with the virtual magnification of the sample. Virtually magnifying a view of the sample includes binning and cropping pixels of the view prior to further magnification. By adjusting the adaptive illumination device, a cross-sectional area of the light beam may be decreased, or its geometry altered. Additionally or alternatively, adjustment of the adaptive illumination device may cause an intensity, phase, and/or polarization of the light beam to be modified. As one example, the light beam may be modulated such that regions of the sample that are outside of a portion of the sample corresponding to the virtual FOV of the OLM are not illuminated. In other examples, the regions outside of the sample portion corresponding to the virtual FOV may be illuminated with less intensity, different phase, or different polarization than within the virtual FOV.

At 914, the method 900 includes acquiring one or more images of the sample at the portion that is virtually magnified. For example, multiple images of the ROI may be obtained at different focal planes and combined to create a 3D image stack. The method 900 then includes returning to 906 to determine whether further magnification of the sample is requested.

### Exemplary Applications

In one example, when 3D image stacks of an ROI of a sample are acquired by a CPDB-iOLM system, e.g., as per the method 900 of FIG. 9, the 3D image stacks may be used to obtain SEM and/or FIB images. The images may be used to guide milling of the sample by the FIB to obtain one or more lamellae. The lamellae may then be observed using the iOLM, e.g., as a third imaging phase, to determine whether target structures or objects identified in the ROI are retained in the lamellae. In at least some instances, fluorescence of fluorophores of the lamellae may be 5 to 20 times darker than surrounding, non-thinned portions of the sample. An adaptive illumination device of the iOLM may be used to create an attenuation mask to reduce an incident light power in the surrounding portions of the sample to 5-25% the incident light power. The creation of the attenuation mask may be requested and selected by the user at, for example, a graphical user interface (GUI) or other suitable user interface.

In another example, high-dynamic range (HDR) imaging may be performed using an adaptive illumination device of a CPDB-iOLM system. For example, the adaptive illumination device may be controlled automatically to circumvent under- or over-exposure of a sample. This may be achieved by modifying an incident light pattern of light emitted by a light source of an iOLM. Resulting images may be high-dynamic range images which may be expanded to full contrast range by multiplying pixel brightness values with a reverse of local light attenuation provided by the pattern. The pattern applied to the incident light via the adaptive illumination device may be saved along with the acquired images.

In yet another example, an adaptive illumination device of a CPDB-iOLM system may be used to perform active shading correction. For example, perfect alignment of OLMs with a sample may be intermittent, brief, or, in some instances, difficult to achieve. Misalignment of an OLM may be evident by appearance of shading artifacts such as gradients, clouds, or drops of brightness towards image borders (e.g., vignetting). For cryogenic samples, these artifacts may be pronounced when image montages are viewed, which is often demanded to observe large sample areas with limited per-image FOVs. By programming the adaptive illumination device to illuminate the sample with respect to a reverse of the shading artifact, flat homogeneous images may be obtained that reduce an effect of the shading artifacts. As a result, a performance of the CPDB-iOLM system may be increased and intervals between a demand for servicing of the CPDB-iOLM system may be prolonged.

In yet another example, an adaptive illumination device of a CPDB-iOLM system may be used to administer light locally in diffraction-limited regions of a sample. For example, there may be spots of <0.5 μm where a resolution of a SEM of the CPDB-iOLM system is insufficient to resolve sample features. The adaptive illumination device may be used to focus illumination with specific parameters (e.g., intensity, phase, or polarization) on the diffraction-limited spots. This may allow photo-activation of fluorophores and/or localized heating and/or melting to modify a sample or sample support.

### Exemplary System Environments

Turning now to FIG. 10, a simplified diagram of a CPDB-iOLM system 1000 is shown. In at least one example, the CPDB-iOLM system 1000 is similar to the CPDB-iOLM system 100 of FIG. 1 and depicts a flow of communication (e.g., transmission of electronic signals) and sample probing techniques (e.g., charged particle and light beams) implemented by the CPDB-iOLM system 1000. The CPDB-iOLM system 1000 includes a control system 1002 (e.g., similar to the control system 150 of FIG. 1) that is coupled to an ion beam source 1004, an electron beam source 1006, and a light source 1008 that produce an ion beam, an electron beam, and a light beam, respectively. The beam of each respective source may be guided to a sample 1010 via a column. For example, an ion beam generated by the ion beam source 1004 may be transmitted through an ion beam column such as the FIB column 111 of FIG. 1, an electron beam generated by the electron beam source 1006 may be transmitted through an electron beam column such as the electron beam column 107 of FIG. 1, and the light beam generated by the light source 1008 may be guided through an OLM such as the OLM 115 of FIG. 1 and the OLM system 200 of FIG. 2. The ion beam column, electron beam column, and OLM may include various components that focus, direct, and otherwise modify the respective beam. In particular, an adaptive illumination device 1012 (abbreviated as AID in FIG. 10) may be included in the OLM to dynamically adjust the light beam from the light source 1008 before the light beam reaches the sample 1010.

The sample 1010 is secured to a stage 1014 that is coupled to a stage controller 1016 that is in turn coupled to the control system 1002. The stage 1014 generally can provide one or more translations, rotations, or tilts as directed by the control system 1002. One or more sample-generated beams 1018 are produced as a result of interaction of one or more charged particle beams 1020 with the sample. The sample-generated beams 1018 are directed to an electron or ion detector 1022 which is coupled to system electronics 1024 which can include one or more analog-to-digital convertors (ADCs), digital to analog-convertors (DACs), amplifiers, and buffers for control of the detector 1022 and processing (amplification, digitization, buffering) of signals associated with the detector 1022. In other examples, a photon detector is used that produces an electrical signal that is further processed by the system electronics. In most practical examples, at least one ADC is used to produce a digitized detector signal that can be stored in one or more tangible computer readable media (shown as image storage 1026) as an image. In other examples, image storage is remote via a communication connection such as a wired or wireless network connection. The sample-generated beams 1018 can be scattered portions of the scanned ion beam, the scanned electron beam, secondary electrons, ions, or neutral atoms. An optical imager, such as one or more cameras 1028, is coupled to produce an image of the sample 1010 to, for example, provide visual feedback to a technician.

The one or more cameras 1028 includes at least one camera (e.g., the camera 118 of FIG. 1 or 218 of FIG. 2) that receives an emission beam 1032 emitted by the sample 1010 that includes target wavelengths. For example, the target wavelengths may be wavelengths specific to fluorescence imaging, bright-field imaging, dark-field imaging, phase-contrast imaging, polarized light imaging, among others. An image of the sample 1010, generated based on the target wavelengths, is recorded by the camera 1028 and then processed by the control system 1002 to produce a final image that is stored at the image storage 1026.

The control system 1002, upon acquiring the image from the camera 1028, may receive an indication, from one or more user input devices 1034, that a portion of the image is to be magnified. The portion of the image may be virtually magnified (e.g., by binning and cropping the image) using algorithms and code to perform image magnification 1036 and the adaptive illumination device 1012 may be instructed, by the control system 1002, to adjust an area of the sample 1010 that is illuminated by the light source 1008.

The control system 1002 is coupled to a memory 1038 that stores processor-executable instructions for image processing and acquisition such as image magnification 1036 concomitant with adjustment of the adaptive illumination device 1012, and to provide a graphical user interface (GUI) 1040 for various functions, including parameters associated with selecting magnification and illumination of the sample 1010.

Images (both CPB and optical) and stage coordinates (including rotations) can be stored in the image storage 1026 portion of the memory 1038. The control system 1002 establishes image acquisition parameters and is in communication with the stage controller 1016. Sample images can be presented on a display 1042, and system control and imaging parameters can be specified using internally stored values from the memory 1038 or provided by a user with the one or more user input devices 1034.

It will be appreciated that the layout of FIG. 10 is for convenient illustration, and actual alignments of various beam sources and other components need not be the same as shown. Components used to establish a suitable vacuum environment are omitted as well. While a dual beam (ion/electron beam) system is illustrated, one or both beams can be used.

FIG. 11 and the following discussion are intended to provide a brief, general description of an exemplary computing environment in which the disclosed technology may be implemented. In particular, some or all portions of this computing environment can be used with the above methods and apparatus to, for example, to acquire images with different magnifications, and control illumination of a sample according to magnification. For example, the exemplary control system 1100 illustrated in FIG. 11 may be included in the control system 150 of FIG. 1 and used as described above with reference to the control system 1002 of FIG. 10. Although not required, the disclosed technology is described in the general context of computer executable instructions, such as program modules, being executed by a computer. Generally, program modules include routines, programs, objects, components, data structures, etc., that perform particular tasks or implement particular abstract data types. Moreover, the disclosed technology may be implemented with other computer system configurations, including handheld devices, tablets, multiprocessor systems, microprocessor-based or programmable consumer electronics, network PCs, minicomputers, mainframe computers, and the like. The disclosed technology may also be practiced in distributed computing environments where tasks are performed by remote processing devices that are linked through a communications network. In a distributed computing environment, program modules may be located in both local and remote memory storage devices. As used herein, the term “processor” refers to CPUs and other logical processing devices such as FPGAs, ASICs, and CPLDs. A control system or other controller generally includes at least one processor as well as additional components such as memory, communication buses, and others as discussed below.

With reference to FIG. 11, an exemplary system for implementing the disclosed technology includes a general-purpose computing device 1102 of the control system 1100 that includes one or more processors, or processing units, 1104, a system memory 1106, and a system bus 1108 that couples various system components including the system memory 1106 to the one or more processors 1104. The system bus 1108 may be any of several types of bus structures including a memory bus or memory controller, a peripheral bus, and a local bus using any of a variety of bus architectures. The exemplary system memory 1106 includes read only memory (ROM) 1110 and random-access memory (RAM) 1112. A basic input/output system (BIOS) 1114, containing the basic routines that help with the transfer of information between elements within the computing device 1102, is stored in ROM 1110.

The computing device 1102 further includes one or more storage devices 1116 such as a hard disk drive for reading from and writing to a hard disk, a magnetic disk drive for reading from or writing to a removable magnetic disk, a memory device such as a thumb drive, and an optical disk drive for reading from or writing to a removable optical disk (such as a CD-ROM or other optical media). Such storage devices can be connected to the system bus 1108 by a hard disk drive interface, a magnetic disk drive interface, and an optical drive interface, respectively. The drives and their associated computer readable media provide nonvolatile storage of computer-readable instructions, data structures, program modules, and other data for the computing device 1102. Other types of computer-readable media which can store data that is accessible by a computing device, such as magnetic cassettes, flash memory cards, digital video disks, CDs, DVDs, RAMs, ROMs, and the like, may also be used in the exemplary operating environment. As used herein, memory, storage devices and the like refer to non-transitory storage, i.e., not propagating signals.

A number of program modules may be stored in the storage devices 1116 including an operating system, one or more application programs, other program modules, and program data. A user may enter commands and information into the computing device 1102 through one or more input devices 1118 such as a keyboard and a pointing device such as a mouse. For example, the user may enter commands to select a region of a sample image to be magnified. Other input devices may include a digital camera, microphone, joystick, game pad, satellite dish, scanner, or the like. These and other input devices are often connected to the one or more processing units 1104 through a serial port interface that is coupled to the system bus 1108 but may be connected by other interfaces such as a parallel port, game port, universal serial bus (USB), or wired or wireless network connection. One or more output devices 1120, such as a monitor or other type of display device, is also connected to the system bus 1108 via an interface, such as a video adapter, and can display, for example, one or ROI images obtained with an OLM, such as a fluorescence light microscope. The output devices 1120 can also be used to aid in CPB instrument control, to confirm successful beams shape control, image acquisition, and selection of deconvolution approach, and other functions. Other peripheral devices, such as speakers and printers (not shown), may be included in the output device 1120. The computing device 1102 may operate in a networked environment using logical connections to one or more remote computers, such as a remote computer 1122. In some examples, one or more network or communication connections 1124 are included. The remote computer 1122 may be another computing device, a server, a router, a network PC, or a peer device or other common network node, and typically includes many or all of the elements described above relative to the computing device 1102, although only a memory storage device 1126 has been illustrated in FIG. 11. The computing device 1102 and/or the remote computer 1122 can be connected to a local area network (LAN) and a wide area network (WAN). Some or all functions provided by the computing device 1102 can be provided by the remote computer 1122.

As shown in FIG. 11, a memory 1128 of the computing device 1102 (or portions of this or other memory) stores processor executable instructions for virtual magnification of an image and adaptive illumination of a sample in conjunction with the virtual magnification. In addition, the memory 1128 can store images, magnification parameters, and adaptive illumination settings that permits magnification and illumination to be set to control an CPDB-iOLM system 1130.

Aspects of the present disclosure are provided in the paragraphs below.

In at least one embodiment, a dual beam system is disclosed, comprising an ion beam column coupled to a chamber surrounding a sample; an electron beam column coupled to the chamber and having a focal point aligned with the sample at a eucentric point of the electron beam column and the ion beam column; an optical light microscope coupled to the chamber, the optical light microscope having a first field of view (FOV), the first FOV corresponding to an area of the sample that is illuminated by the optical light microscope, that is to be superimposed with data collected using one or more of the ion beam column or the electron beam column, wherein the optical light microscope comprises an adaptive illumination device to adjust illumination of the area of the sample. The dual beam system may further include wherein the adaptive illumination device is located in the optical light microscope external to the chamber.

The dual beam system may also include wherein the adaptive illumination device is used to decrease illumination of regions of the sample outside of a second FOV of the optical light microscope, and wherein the second FOV comprises a smaller area of the sample than the first FOV. Additionally, the dual beam system can include wherein the optical light microscope is a wide-field optical light microscope, and wherein the adaptive illumination device is used to decrease the area of the sample that is illuminated by a broad light source, and wherein the adaptive illumination device is one of a spatial light modulator, a digital micromirror device, or a motorized field stop.

The dual beam system may further comprise a controller having stored thereon executable instructions that, when executed, cause the controller to identify a change in virtual magnification of the first FOV of the optical light microscope; and adjust, based at least in part on the change in the virtual magnification, an amount of light that illuminates the sample, the light emitted by a light source of the optical light microscope. The dual beam system may also include a controller having stored thereon executable instructions that, when executed, cause the controller to cause the adaptive illumination device to decrease illumination of the sample by the optical light microscope based on a second FOV of the optical light microscope, wherein the second FOV is a virtual magnification of a sub-area of the area of the sample that is illuminated in the first FOV.

Furthermore, the dual beam system may include a controller having stored thereon executable instructions that, when executed, cause the controller to cause the adaptive illumination device to decrease illumination of an outer region of the sample, the outer region being outside of a sub-area of the area of the sample that is illuminated in the first FOV, wherein the sub-area is observed in a second FOV of the optical light microscope, and wherein the second FOV is a virtually magnified view of the sub-area relative to the first FOV.

In at least one other embodiment, a method for a dual beam system is disclosed, comprising identifying a region of interest (ROI) of a sample using an optical light microscope coupled to a chamber surrounding the sample, the chamber also coupled to an electron beam column and an ion beam column; receiving a request for virtual magnification of a first field of view (FOV) of the optical light microscope to a second FOV; in response to the received request, adjusting, using an adaptive illumination device of the optical light microscope, illumination of the sample in a region outside of the second FOV; and using the second FOV to apply to the sample one or more of an electron beam generated by the electron beam column or an ion beam generated by the ion beam column.

The method may include wherein identifying the ROI comprises illuminating the sample with light to detect fluorescent light emitted by the sample. The method may also include wherein the virtual magnification is obtained based, at least in part, on binning and cropping an image of the sample acquired by the optical light microscope using the first FOV. Additionally, the method may include wherein the second FOV is a magnified view of a sub-area of an area of the sample observed in the first FOV, and wherein the first and second FOVs of the optical light microscope are obtained using an objective of the optical light microscope, the objective having a magnification of 20×, a numerical aperture of 0.7, and a working distance of 1.3 mm.

The method may further include wherein the optical light microscope is a fluorescence light microscope, and wherein the sample is a cryogenic sample illuminated by the optical light microscope within a cryogenic environment of the chamber. The method may also include wherein the illumination of the sample outside of the second FOV is adjusted by varying one or more of an intensity, a phase, a polarity, or a cross-sectional geometry of a beam of light generated by a light source of the optical light microscope.

In yet another embodiment, a charged particle dual beam apparatus is disclosed, comprising an electron beam column configured to scan a sample within a vacuum chamber using an electron beam; an ion beam column configured to apply an ion beam to the sample; an optical light microscope having a field of view (FOV) aligned with the sample and comprising an adaptive illumination device; and a controller having executable instructions thereon that, when executed, cause the controller to identify one or more regions of interest (ROIs) in the sample using the optical light microscope; operate the adaptive illumination device to adjust illumination of the sample outside of the field of view (FOV) of the optical light microscope; and use one or more images obtained by the optical light microscope to apply, to the sample, one or more of the electron beam or the ion beam.

The charged particle dual beam apparatus may further include wherein the sample is milled using the ion beam to obtain a sub-sample of the sample, the sub-sample comprising an ROI identified in the FOV of the optical light microscope, and wherein the executable instructions that cause the controller to operate the adaptive illumination device are further to cause the controller to use the adaptive illumination device to generate an attenuation mask; cause the attenuation mask to be applied to the sub-sample; and determine, using the optical light microscope, whether the ROI is observed in the sub-sample.

The charged particle dual beam apparatus may also include wherein the executable instructions that cause the controller to operate the adaptive illumination device are further to cause the controller to use the adaptive illumination device to modify an incident light pattern of the optical light microscope to obtain high-dynamic range (HDR) images. Additionally, the charged particle dual beam apparatus may include wherein the executable instructions that cause the controller to operate the adaptive illumination device are further to cause the controller to operate the electron beam column to identify diffraction-limited regions of less than 0.5 μm of the sample; and use the adaptive illumination device to selectively illuminate the identified diffraction-limited regions.

Furthermore, the charged particle dual beam apparatus may include wherein the executable instructions that cause the controller to operate the adaptive illumination device are further to cause the controller to use the adaptive illumination device to selectively illuminate the sample based on one or more shading artifacts observed in an image of the sample obtained by the optical light microscope.

While the present disclosure has been described in detail with reference to specific embodiments, it will be apparent to those skilled in the art that various modifications and changes can be made without departing from the spirit and scope of the disclosure. Accordingly, the specification and drawings are to be regarded in an illustrative rather than a restrictive sense.

What is claimed is:

1. A dual beam system, comprising:
an ion beam column coupled to a chamber surrounding a sample;
an electron beam column coupled to the chamber and having a focal point aligned with the sample at a eucentric point of the electron beam column and the ion beam column;
an optical light microscope coupled to the chamber, the optical light microscope having a first field of view (FOV), the first FOV corresponding to an area of the sample that is illuminated by the optical light microscope, that is to be superimposed with data collected using one or more of the ion beam column or the electron beam column, wherein the optical light microscope comprises an adaptive illumination device to adjust illumination of the area of the sample.

2. The dual beam system of claim 1, wherein the adaptive illumination device is located in the optical light microscope external to the chamber.

3. The dual beam system of claim 1, wherein the adaptive illumination device is used to decrease illumination of regions of the sample outside of a second FOV of the optical light microscope, and wherein the second FOV comprises a smaller area of the sample than the first FOV.

4. The dual beam system of claim 1, wherein the optical light microscope is a wide-field optical light microscope, and wherein the adaptive illumination device is used to decrease the area of the sample that is illuminated by a broad light source.

5. The dual beam system of claim 1, wherein the adaptive illumination device is one of a spatial light modulator, a digital micromirror device, or a motorized field stop.

6. The dual beam system of claim 1, further comprising a controller having stored thereon executable instructions that, when executed, cause the controller to:
identify a change in virtual magnification of the first FOV of the optical light microscope; and
adjust, based, at least in part, on the change in the virtual magnification, an amount of light that illuminates the sample, the light emitted by a light source of the optical light microscope.

7. The dual beam system of claim 1, further comprising a controller having stored thereon executable instructions that, when executed, cause the controller to:
cause the adaptive illumination device to decrease illumination of the sample by the optical light microscope based on a second FOV of the optical light microscope, wherein the second FOV is a virtual magnification of a sub-area of the area of the sample that is illuminated in the first FOV.

8. The dual beam system of claim 1, further comprising a controller having stored thereon executable instructions that, when executed, cause the controller to:
cause the adaptive illumination device to decrease illumination of an outer region of the sample, the outer region being outside of a sub-area of the area of the sample that is illuminated in the first FOV, wherein the sub-area is observed in a second FOV of the optical light microscope, and wherein the second FOV is a virtually magnified view of the sub-area relative to the first FOV.

9. A method for a dual beam system, comprising:
identifying a region of interest (ROI) of a sample using an optical light microscope coupled to a chamber surrounding the sample, the chamber also coupled to an electron beam column and an ion beam column;
receiving a request for virtual magnification of a first field of view (FOV) of the optical light microscope to a second FOV;
in response to the received request, adjusting, using an adaptive illumination device of the optical light microscope, illumination of the sample in a region outside of the second FOV; and
using the second FOV to apply to the sample one or more of an electron beam generated by the electron beam column or an ion beam generated by the ion beam column.

10. The method of claim 9, wherein identifying the ROI comprises illuminating the sample with light to detect fluorescent light emitted by the sample.

11. The method of claim 9, wherein the virtual magnification is obtained based, at least in part, on binning and cropping an image of the sample acquired by the optical light microscope using the first FOV.

12. The method of claim 9, wherein the second FOV is a magnified view of a sub-area of an area of the sample observed in the first FOV.

13. The method of claim 9, wherein the first and second FOVs of the optical light microscope are obtained using an objective of the optical light microscope, the objective having a magnification of 20×, a numerical aperture of 0.7, and a working distance of 1.3 mm.

14. The method of claim 9, wherein the optical light microscope is a fluorescence light microscope, and wherein the sample is a cryogenic sample illuminated by the optical light microscope within a cryogenic environment of the chamber.

15. The method of claim 9, wherein the illumination of the sample outside of the second FOV is adjusted by varying one or more of an intensity, a phase, a polarity, or a cross-sectional geometry of a beam of light generated by a light source of the optical light microscope.

16. A charged particle dual beam apparatus, comprising:
an electron beam column configured to scan a sample within a vacuum chamber using an electron beam;
an ion beam column configured to apply an ion beam to the sample;
an optical light microscope having a field of view (FOV) aligned with the sample and comprising an adaptive illumination device; and
a controller having executable instructions thereon that, when executed, cause the controller to:
identify one or more regions of interest (ROIs) in the sample using the optical light microscope;
operate the adaptive illumination device to adjust illumination of the sample outside of the field of view (FOV) of the optical light microscope; and
use one or more images obtained by the optical light microscope to apply, to the sample, one or more of the electron beam or the ion beam.

17. The charged particle dual beam apparatus of claim 16, wherein the sample is milled using the ion beam to obtain a sub-sample of the sample, the sub-sample comprising an ROI identified in the FOV of the optical light microscope, and wherein the executable instructions that cause the controller to operate the adaptive illumination device are further to cause the controller to:
use the adaptive illumination device to generate an attenuation mask;
cause the attenuation mask to be applied to the sub-sample; and
determine, using the optical light microscope, whether the ROI is observed in the sub-sample.

18. The charged particle dual beam apparatus of claim 16, wherein the executable instructions that cause the controller to operate the adaptive illumination device are further to cause the controller to use the adaptive illumination device to modify an incident light pattern of the optical light microscope to obtain high-dynamic range (HDR) images.

19. The charged particle dual beam apparatus of claim 16, wherein the executable instructions that cause the controller to operate the adaptive illumination device are further to cause the controller to:
operate the electron beam column to identify diffraction-limited regions of less than 0.5 μm of the sample; and
use the adaptive illumination device to selectively illuminate the identified diffraction-limited regions.

20. The charged particle dual beam apparatus of claim 16, wherein the executable instructions that cause the controller to operate the adaptive illumination device are further to cause the controller to:
use the adaptive illumination device to selectively illuminate the sample based on one or more shading artifacts observed in an image of the sample obtained by the optical light microscope.
